(19) United States
(12) Patent Application Publication
(10) Pub. No.: US 2025/0220941 A1
(43) Pub. Date: Jul. 3, 2025

(54) METHOD FOR MANUFACTURING SEMICONDUCTOR STRUCTURE

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/619,664

(22) Filed: Mar. 28, 2024

(30) Foreign Application Priority Data
Dec. 29, 2023 (CN) 202311850137.1

(51) Int. Cl. H01L 29/66; H01L 21/225; H01L 21/3065; H01L 29/20; H01L 29/778

(52) U.S. Cl. CPC H10D 30/015; H01L 21/2258; H10D 30/475; H01L 21/3065; H10D 62/8503

(57) ABSTRACT

A method for manufacturing a semiconductor structure includes: growing a channel layer, a barrier layer and an n-type semiconductor layer on a substrate sequentially; etching a trench on the n-type semiconductor layer, where the trench penetrates through the n-type semiconductor layer; growing a sacrificial layer on the n-type semiconductor layer and in the trench; etching the sacrificial layer; repeating the growth and etching of the sacrificial layer multiple times until a concentration of an impurity element on a surface of the barrier layer below the trench is less than a preset value; and growing a p-type semiconductor layer on the n-type semiconductor layer and in the trench. The technical solutions of the present disclosure may improve the reliability of a device.

### CROSS-REFERENCE TO RELATED APPLICATIONS

The present application claims priority to Chinese Patent Application No. 202311850137.1, filed on Dec. 29, 2023, which is hereby incorporated by reference in its entirety.

### TECHNICAL FIELD

The present disclosure relates to the field of semiconductor technologies, and in particular, to a method for manufacturing a semiconductor structure.

### BACKGROUND

A High Electron Mobility Transistor (HEMT) is a heterojunction field effect transistor. Taking an AlGaN/GaN heterostructure as an example, due to a strong two-dimensional electron gas in the AlGaN/GaN heterostructure, an AlGaN/GaN HEMT is usually a depletion mode device, which makes it difficult to implement an enhancement mode device. However, the application of depletion mode devices has certain limitations in some conditions. For example, in applications of power switching devices, enhancement mode (normally-off) switching devices are required. Enhancement mode GaN switching devices are mainly used in high-frequency devices, power switching devices, digital circuits and the like, and its research is of great significance. There are a plurality of implementations of the enhancement mode device, for example, a p-type semiconductor is disposed on a barrier layer of a gate region to deplete a two-dimensional electron gas, but there are usually a large amount of impurities at a contact interface between the barrier layer and the p-type semiconductor, so that an interface quality of the barrier layer and the p-type semiconductor may be reduced, resulting in current leakage, reducing a reliability of a gate, and finally affecting performances of the device.

### SUMMARY

In view of this, embodiments of the present disclosure provide a method for manufacturing a semiconductor structure to reduce impurities between a barrier layer and a p-type semiconductor in an enhancement mode device, thereby improving a reliability of the device.

According to an aspect of the present disclosure, an embodiment of the present disclosure provides a method for manufacturing a semiconductor structure, which includes:
growing a channel layer, a barrier layer and an n-type semiconductor layer on a substrate sequentially;
etching a trench on the n-type semiconductor layer, where the trench penetrates through the n-type semiconductor layer;
growing a sacrificial layer on the n-type semiconductor layer and in the trench;
etching the sacrificial layer; and
growing a p-type semiconductor layer on the n-type semiconductor layer and in the trench.

Before performing the growing a p-type semiconductor layer on the n-type semiconductor layer and in the trench, the growing a sacrificial layer on the n-type semiconductor layer and in the trench and the etching the sacrificial layer is repeated N times until a concentration of an impurity element on a surface of the barrier layer below the trench is less than a preset value.

As an optional embodiment, the trench penetrates through the n-type semiconductor layer and partially penetrates through the barrier layer.

As an optional embodiment, a method for etching the trench includes in-situ etching.

As an optional embodiment, the in-situ etching includes dry etching.

As an optional embodiment, a gas atmosphere for etching the trench includes one or a combination of more of Cl₂, H₂, HCl and tertiarybutylchloride (TBCl).

As an optional embodiment, after forming the trench by the in-situ etching, the method further includes:
performing a second etching on the trench, and forming a plurality of V pits or hexagonal prisms arranged at intervals on a bottom surface of the trench.

As an optional embodiment, before etching the trench on the n-type semiconductor layer, the method further includes:
disposing a first insertion layer on the n-type semiconductor layer, where a material of the first insertion layer includes AlGaN.

As an optional embodiment, the growing a channel layer, a barrier layer and an n-type semiconductor layer on a substrate sequentially includes:
growing the channel layer, the barrier layer, a second insertion layer and the n-type semiconductor layer on the substrate sequentially, where the second insertion layer is an unintentional doped layer.

As an optional embodiment, a material of the n-type semiconductor layer includes at least one of n-type GaN, n-type AlGaN or n-type AlInGaN.

As an optional embodiment, the sacrificial layer is conformally grown on the n-type semiconductor layer and in the trench, or, a surface, away from the substrate, of the sacrificial layer is a plane.

As an optional embodiment, a method for etching the sacrificial layer includes in-situ etching.

As an optional embodiment, a material of the sacrificial layer includes one or a combination of more of AlN, InN, InGaN, InAlN, InAlGaN or GaN.

As an optional embodiment, the sacrificial layer is an unintentional doped layer.

As an optional embodiment, the sacrificial layer is a carbon-doped layer, an iron-doped layer or an iron-carbon co-doped layer.

As an optional embodiment, the p-type semiconductor layer is conformally grown on the n-type semiconductor layer and in the trench, or, a surface, away from the substrate, of the p-type semiconductor layer is a plane.

As an optional embodiment, a material of the p-type semiconductor layer includes at least one of p-type diamond, p-type NiO, p-type single crystal GaN or p-type polycrystalline GaN.

As an optional embodiment, the method further includes: etching the n-type semiconductor layer to expose the barrier layer, and form a source region and a drain region, disposing a source electrode in the source region, disposing a drain electrode in the drain region, and disposing a gate electrode on the p-type semiconductor layer located on the trench.

### BRIEF DESCRIPTION OF THE DRAWINGS

FIG. 1 is a schematic flowchart of a method for manufacturing a semiconductor structure according to an embodiment of the present disclosure.

FIG. 2 to FIG. 11 are schematic structural diagrams of intermediate structures corresponding to the flowchart of FIG. 1.

FIG. 12a to FIG. 12c are schematic structural diagrams of semiconductor structures according to some embodiments of the present disclosure.

### DETAILED DESCRIPTION OF THE EMBODIMENTS

Technical solutions in embodiments of the present disclosure are described clearly and completely below with reference to the drawings of the embodiments of the present disclosure. Apparently, the described embodiments are only a part, but not all of the embodiments of the present disclosure. All other embodiments that may be obtained by those of ordinary skill in the art based on the embodiments in the present disclosure without any inventive efforts fall into the protection scope of the present disclosure.

In order to reduce impurities between a barrier layer and a p-type semiconductor in an enhancement mode device, and improve a reliability of the device, the present disclosure provides a method for manufacturing a semiconductor structure. The manufacturing method includes: growing a channel layer, a barrier layer and an n-type semiconductor layer on a substrate sequentially; etching a trench on the n-type semiconductor layer, where the trench penetrates through the n-type semiconductor layer; growing a sacrificial layer on the n-type semiconductor layer and in the trench; etching the sacrificial layer; repeating the growth and etching of the sacrificial layer multiple times until a concentration of an impurity element on a surface of the barrier layer below the trench is less than a preset value; and growing a p-type semiconductor layer on the n-type semiconductor layer and in the trench. In the present disclosure, by a method of growing the sacrificial layer and etching the sacrificial layer for several times, a concentration of an impurity element on a surface of the barrier layer below the trench is reduced, and a concentration of an impurity element in an epitaxial chamber is also reduced, thereby improving an interface quality between the barrier layer and the p-type semiconductor layer, further improving a crystal quality of the p-type semiconductor layer, reducing a leakage current of a gate and further improving stability and a reliability of a device.

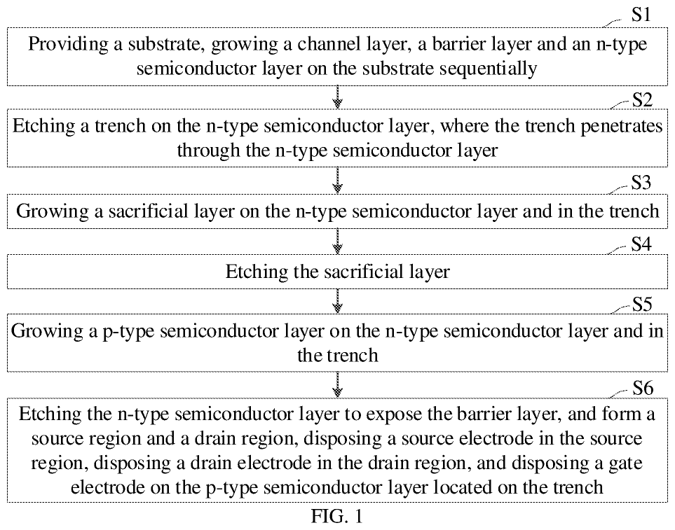

The method for manufacturing the semiconductor structure mentioned in the present disclosure is further illustrated with examples below with reference to FIG. 1 to FIG. 12c.

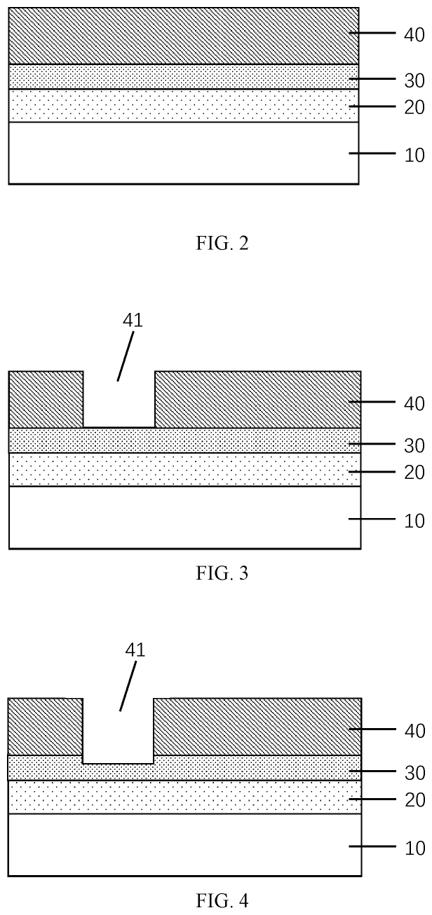

FIG. 1 is a schematic flowchart of a method for manufacturing a semiconductor structure according to an embodiment of the present disclosure; and FIG. 2 to FIG. 11 are schematic structural diagrams of intermediate structures corresponding to the flowchart of FIG. 1. As shown in FIG. 1, a method for manufacturing a semiconductor structure provided by an embodiment of the present disclosure may include following steps.

Step S1: providing a substrate, growing a channel layer, a barrier layer and an n-type semiconductor layer on the substrate sequentially.

Specifically, as shown in FIG. 2, a substrate 10 is provided, and a channel layer 20, a barrier layer 30 and an n-type semiconductor layer 40 are grown on the substrate 10 sequentially. A material of the substrate 10 includes any one or a combination of more of Si, Al₂O₃, GaN, SiC or AlN. A band gap width of a material of the barrier layer 30 is greater than a band gap width of a material of the channel layer 20. The material of the channel layer 20 and the material of the barrier layer 30 may include group III nitride materials, and a two-dimensional electron gas may be formed at an interface between the channel layer 20 and the barrier layer 30. In an optional solution, the channel layer 20 is a GaN layer, and the barrier layer 30 is an AlGaN layer. In other optional solutions, a combination of materials of the channel layer 20 and the barrier layer 30 may also be GaN/AlN, GaN/InN, GaN/InAlGaN, GaAs/AlGaAs, GaN/InAlN or InN/InAlN. A material of the n-type semiconductor layer 40 includes at least one of n-type GaN, n-type AlGaN or n-type AlInGaN.

Step S2: etching a trench on the n-type semiconductor layer, where the trench penetrates through the n-type semiconductor layer.

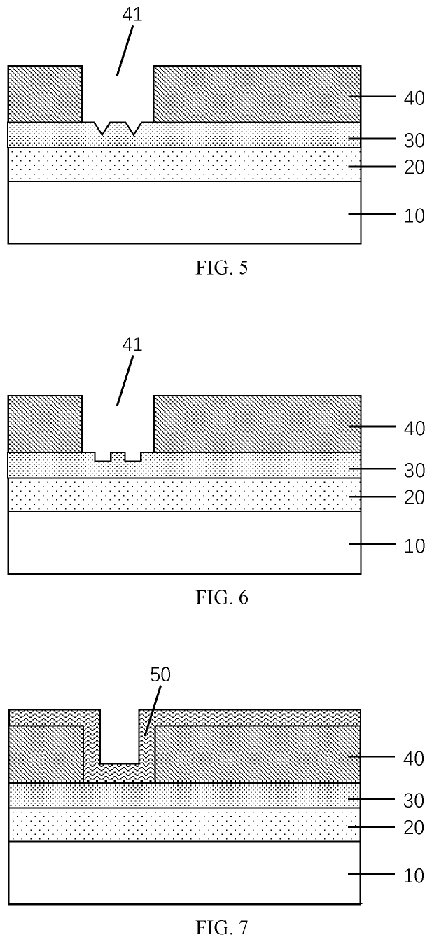

Specifically, as shown in FIG. 3, a trench 41 is etched on the n-type semiconductor layer 40, and the trench 41 penetrates through the n-type semiconductor layer 40. A method for etching the trench 41 includes in-situ etching, a method of the in-situ etching includes dry etching, and a gas atmosphere for etching the trench 41 includes one or a combination of more of Cl₂, H₂, HCl and tertiarybutylchloride (TBCl). The method of the in-situ etching does not introduce impurities, so that an interface state density may be reduced, which is beneficial for reducing a current collapse effect and reducing the leakage current for a subsequent preparation device. Optionally, as shown in FIG. 4, the trench 41 penetrates through the n-type semiconductor layer 40 and partially penetrates through the barrier layer 30, and reduction of a thickness of the barrier layer 30 may further improve a depletion effect of a p-type semiconductor material grown in the trench 41 on the two-dimensional electron gas, thereby improving a threshold voltage of a device. Optionally, after forming the trench 41 by the in-situ etching, a second etching is performed on the trench 41 to form a plurality of V pits (shown in FIG. 5) or hexagonal prisms (shown in FIG. 6) arranged at intervals on a bottom surface of the trench 41, so as to form a crystal plane, for example, a crystal plane of a bottom surface of the trench 41 is a crystal plane (1-100) or a crystal plane (11-20), in this way, the crystal quality of the p-type semiconductor material grown in the trench 41 may be further improved.

Step S3: growing a sacrificial layer on the n-type semiconductor layer and in the trench.

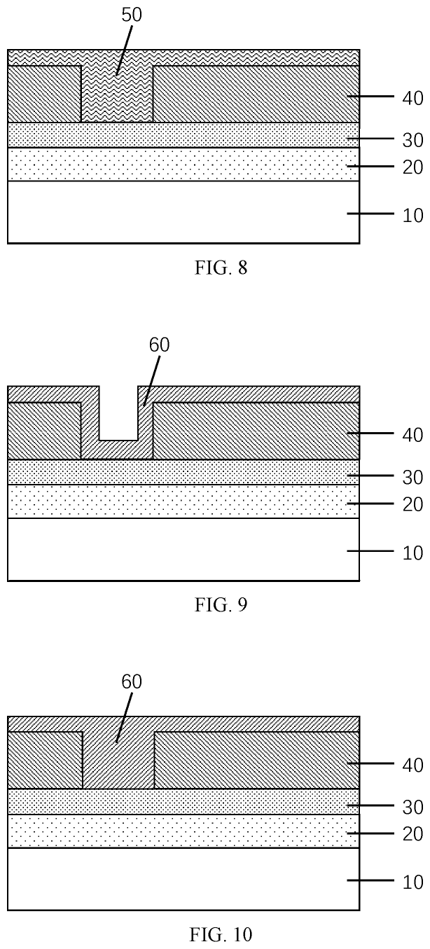

Specifically, a sacrificial layer 50 is grown on the n-type semiconductor layer 40 and in the trench 41. As shown in FIG. 7, the sacrificial layer 50 is conformally grown on the n-type semiconductor layer 40 and in the trench 41; and as shown in FIG. 8, a surface, away from the substrate 10, of the sacrificial layer 50 is a plane. A material of the sacrificial layer 50 includes one or a combination of more of AlN, InN, InGaN, InAlN, InAlGaN or GaN. In some embodiments, the structure of the FIG. 8 may be placed in an epitaxial chamber to realize epitaxial growth. The sacrificial layer 50 is an unintentional doped layer, impurity elements on the surface of the barrier layer 30 below the trench 41 may diffuse into the sacrificial layer 50, and impurity elements in the epitaxial chamber may also diffuse into the sacrificial layer 50, thereby reducing impurity elements on the surface of the barrier layer 30 below the trench 41 and impurity elements in the epitaxial chamber. Optionally, the sacrificial layer 50 is a carbon-doped layer, an iron-doped layer or an iron-carbon co-doped layer. Further, carbon doping, iron doping or iron-carbon co-doping of the sacrificial layer 50 may be gradual doping. A deep energy level trap may be formed by doping iron or carbon in the sacrificial layer 50, which provides a recombination center, and captures holes or electrons on the surface of the barrier layer 30 below the trench 41, thereby reducing the concentration of impurity elements on the surface of the barrier layer 30 below the trench 41, and reducing the concentration of impurity elements in the epitaxial chamber.

Step S4: etching the sacrificial layer.

Specifically, the sacrificial layer 50 is etched, and an intermediate structure shown in FIG. 3 or in FIG. 4 is formed. A method for etching the sacrificial layer 50 includes in-situ etching, the method of the in-situ etching does not introduce impurities, so that an interface state density may be reduced, which is beneficial for reducing a current collapse effect and reducing the leakage current for a subsequent preparation device.

Step S3 and Step S4 may be repeated N times until a concentration of an impurity element on a surface of the barrier layer 30 below the trench 41 is less than a preset value. By repeating Step S3 and Step S4 N times, a concentration of an impurity element on a surface of the barrier layer 30 below the trench 41 may be reduced, and a concentration of an impurity element in the epitaxial chamber may also be reduced, thereby improving an interface quality between the barrier layer 30 and the p-type semiconductor layer 60, further improving the crystal quality of the p-type semiconductor layer 60, reducing the leakage current of the gate and further improving the stability and the reliability of the device.

Step S5: growing a p-type semiconductor layer on the n-type semiconductor layer and in the trench.

Specifically, a p-type semiconductor layer 60 is grown on the n-type semiconductor layer 40 and in the trench 41. As shown in FIG. 9, the p-type semiconductor layer 60 is conformally grown on the n-type semiconductor layer 40 and in the trench 41; and as shown in FIG. 10, a surface, away from the substrate 10, of the p-type semiconductor layer 60 is a plane. The n-type semiconductor layer 40 is completely covered by the p-type semiconductor layer 60. Since the n-type semiconductor layer 40 may perform electron compensation on the channel layer 20, influence of a surface state on the two-dimensional electron gas is avoided. Therefore, there is no need to selectively etch all part, except for a gate region, of the p-type semiconductor material, and a conduction requirement of a device may still be satisfied. A material of the p-type semiconductor layer 60 includes at least one of p-type diamond, p-type NiO, p-type single crystal GaN or p-type polycrystalline GaN.

In some embodiments, the method for manufacturing the semiconductor structure may further include following steps.

Step S6: etching the n-type semiconductor layer to expose the barrier layer, and form a source region and a drain region, disposing a source electrode in the source region, disposing a drain electrode in the drain region, and disposing a gate electrode on the p-type semiconductor layer located on the trench.

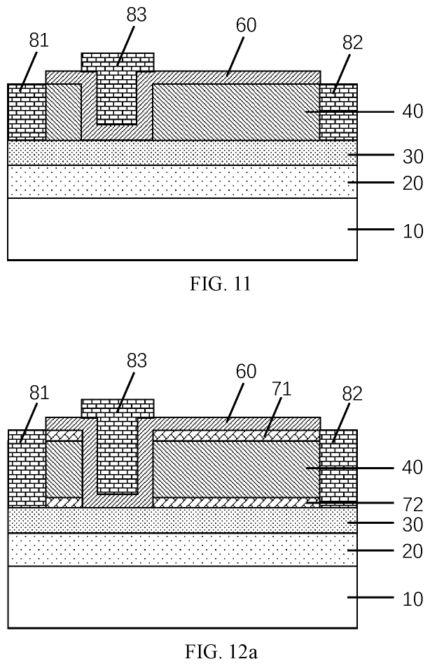

Specifically, a semiconductor structure as shown in FIG. 11 may be formed by etching the n-type semiconductor layer 40 to expose the barrier layer 30 and form a source region and a drain region, disposing a source electrode 81 in the source region, disposing a drain electrode 82 in the drain region, and disposing a gate electrode 83 on the p-type semiconductor layer 60 located on the trench 41.

According to the semiconductor structure provided by the embodiments of the present disclosure, the n-type semiconductor layer 40 is formed on the barrier layer 30, the trench 41 is formed in the gate region of the n-type semiconductor layer 40, and the p-type semiconductor layer 60 is disposed at the trench 41, which may achieve a purpose of pinching off an n-type conductive layer below the gate electrode to realize an enhancement mode switching device. Since the n-type semiconductor layer 40 may perform electron compensation on the channel layer 20, influence of a surface state on the two-dimensional electron gas is avoided. Therefore, there is no need to selectively etch all part, except for a gate region, of the p-type semiconductor material, and a conduction requirement of a device may still be satisfied, thereby reducing difficulty of a process, and improving the stability and the reliability of the device.

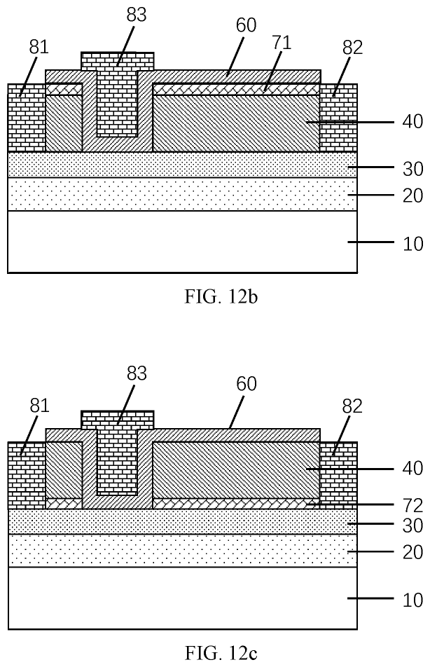

FIG. 12a to FIG. 12c are schematic structural diagrams of semiconductor structures according to some embodiments of the present disclosure. In an embodiment, as shown in FIG. 12a, before etching the trench 41 on the n-type semiconductor layer 40, a first insertion layer 71 may be further disposed on the n-type semiconductor layer 40, and a material of the first insertion layer 71 includes AlGaN. Optionally, the first insertion layer 71 is an unintentional doped layer, and a second insertion layer 72 is disposed between the barrier layer 30 and the n-type semiconductor layer 40. The second insertion layer 72 is an unintentional doped layer. On an aspect, the disposition of the first insertion layer 71 may add a discrete energy level between the p-type semiconductor layer 60 and the n-type semiconductor layer 40, thereby adjusting an energy band structure, avoiding accumulation of carriers in a device, and making a distribution of the carriers more uniform; on another aspect, the disposition of the first insertion layer 71 may further prevent influence of holes in the p-type semiconductor layer 60 on the two-dimensional electron gas in the channel layer of a non-gate region, thereby enhancing a conduction property of a device; and on yet another aspect, the disposition of the first insertion layer 71 may passivate a surface of the n-type semiconductor layer 40 for protection. On an aspect, the second insertion layer 72 may further protect the lower barrier layer 30, and on another aspect, similarly, the second insertion layer 72 may further prevent influence of holes in the p-type semiconductor layer 60 on the two-dimensional electron gas in the channel layer of a non-gate region, thereby enhancing a conduction property of a device. However, it should be understood, in an embodiment of the present disclosure, according to actual design requirements, the semiconductor structure may also only include the first insertion layer 71 (shown in FIG. 12b), or only include the second insertion layer 72 (shown in FIG. 12c). Optionally, as shown in FIG. 12b, when the semiconductor structure only includes the first insertion layer 71, a method of etching the trench 41 may include two-step etching, that is, firstly etching the first insertion layer 71 by dry etching, and then etching the n-type semiconductor layer 40 by in-situ etching, so that the trench 41 is formed. The method of two-step etching may further improve the crystal quality of a surface of the trench 41, thereby improving the crystal quality of the p-type semiconductor layer 60 grown in the trench. Optionally, as shown in FIG. 12c, when the semiconductor structure only includes the second insertion layer 72, only the n-type semiconductor layer 40 may be etched to form the trench 41, or the n-type semiconductor layer 40 and the second insertion layer 72 are be etched to form the trench 41. When etching the n-type semiconductor layer 40 and the second insertion layer 72 to form the trench 41, the method for etching may include two-step etching, that is, firstly etching the n-type semiconductor layer 40, and then etching the second insertion layer 72. The method of two-step etching may further improve the crystal quality of the surface of the trench 41, thereby improving the crystal quality of the p-type semiconductor layer 60 grown in the trench. In other embodiments, the n-type semiconductor layer 40 and the second insertion layer 72 may be etched by a method of in-situ etching, and thus a process may be simplified.

The present disclosure provides a method for manufacturing a semiconductor structure, the method includes: growing a channel layer, a barrier layer and an n-type semiconductor layer on a substrate sequentially; etching a trench on the n-type semiconductor layer, where the trench penetrates through the n-type semiconductor layer; growing a sacrificial layer on the n-type semiconductor layer and in the trench; etching the sacrificial layer; repeating the growth and etching of the sacrificial layer multiple times until a concentration of an impurity element on a surface of the barrier layer below the trench is less than a preset value; and growing a p-type semiconductor layer on the n-type semiconductor layer and in the trench.

In the present disclosure, by a method of growing the sacrificial layer and etching the sacrificial layer for several times, a concentration of an impurity element on a surface of the barrier layer below the trench is reduced, and a concentration of an impurity element in an epitaxial chamber is also reduced, thereby improving an interface quality between the barrier layer and the p-type semiconductor layer, further improving a crystal quality of the p-type semiconductor layer, reducing a leakage current of a gate and further improving stability and a reliability of a device.

It should be understood that the terms “including” and its modification used in this disclosure are open-ended, that is, “including but not limited to”. The term “an embodiment” represents “at least one embodiment”; and the term “another embodiment” means “at least one another embodiment”. In this specification, a schematic description of foregoing terms does not have to be directed to a same embodiment or example. Further, specific features, structures, materials, or features described may be incorporated in an appropriate manner in any one or more embodiments or examples. In addition, without being contradictory, a person skilled in the art may combine and permutate different embodiments or examples described in this specification and features of different embodiments or examples.

The foregoing descriptions are merely exemplary embodiments of the present disclosure, and are not intended to limit the present disclosure. Any modification, an equivalent replacement, or the like made within a spirit and principles of the present disclosure shall be included in a protection scope of the present disclosure.

What is claimed is:

1. A method for manufacturing a semiconductor structure, comprising:
growing a channel layer, a barrier layer and an n-type semiconductor layer on a substrate sequentially;
etching a trench on the n-type semiconductor layer, wherein the trench penetrates through the n-type semiconductor layer;
growing a sacrificial layer on the n-type semiconductor layer and in the trench;
etching the sacrificial layer; and
growing a p-type semiconductor layer on the n-type semiconductor layer and in the trench,
wherein before performing the growing a p-type semiconductor layer on the n-type semiconductor layer and in the trench, the growing a sacrificial layer on the n-type semiconductor layer and in the trench and the etching the sacrificial layer is repeated N times until a concentration of an impurity element on a surface of the barrier layer below the trench is less than a preset value.

2. The method for manufacturing the semiconductor structure according to claim 1, wherein the trench penetrates through the n-type semiconductor layer and partially penetrates through the barrier layer.

3. The method for manufacturing the semiconductor structure according to claim 1, wherein a method for etching the trench comprises in-situ etching.

4. The method for manufacturing the semiconductor structure according to claim 3, wherein the in-situ etching comprises dry etching.

5. The method for manufacturing the semiconductor structure according to claim 3, wherein a gas atmosphere for etching the trench comprises one or a combination of more of Cl₂, H₂, HCl and tertiarybutylchloride (TBCl).

6. The method for manufacturing the semiconductor structure according to claim 3, wherein after forming the trench by the in-situ etching, the method further comprises:
performing a second etching on the trench, and forming a plurality of V pits or hexagonal prisms arranged at intervals on a bottom surface of the trench.

7. The method for manufacturing the semiconductor structure according to claim 6, wherein a crystal plane of the bottom surface of the trench comprises a crystal plane (1-100) or a crystal plane (11-20).

8. The method for manufacturing the semiconductor structure according to claim 1, wherein before etching the trench on the n-type semiconductor layer, the method further comprises:
disposing a first insertion layer on the n-type semiconductor layer, wherein a material of the first insertion layer comprises AlGaN.

9. The method for manufacturing the semiconductor structure according to claim 1, wherein the growing a channel layer, a barrier layer and an n-type semiconductor layer on a substrate sequentially comprises:
growing the channel layer, the barrier layer, a second insertion layer and the n-type semiconductor layer on the substrate sequentially, wherein the second insertion layer is an unintentional doped layer.

10. The method for manufacturing the semiconductor structure according to claim 1, wherein a material of the n-type semiconductor layer comprises at least one of n-type GaN, n-type AlGaN or n-type AlInGaN.

11. The method for manufacturing the semiconductor structure according to claim 1, wherein the sacrificial layer is conformally grown on the n-type semiconductor layer and in the trench.

12. The method for manufacturing the semiconductor structure according to claim 1, wherein a surface, away from the substrate, of the sacrificial layer is a plane.

13. The method for manufacturing the semiconductor structure according to claim 1, wherein a method for etching the sacrificial layer comprises in-situ etching.

14. The method for manufacturing the semiconductor structure according to claim 1, wherein a material of the sacrificial layer comprises one or a combination of more of AlN, InN, InGaN, InAlN, InAlGaN or GaN.

15. The method for manufacturing the semiconductor structure according to claim 14, wherein the sacrificial layer is an unintentional doped layer.

16. The method for manufacturing the semiconductor structure according to claim 14, wherein the sacrificial layer is a carbon-doped layer, an iron-doped layer or an iron-carbon co-doped layer.

17. The method for manufacturing the semiconductor structure according to claim 1, wherein the p-type semiconductor layer is conformally grown on the n-type semiconductor layer and in the trench.

18. The method for manufacturing the semiconductor structure according to claim 1, wherein a surface, away from the substrate, of the p-type semiconductor layer is a plane.

19. The method for manufacturing the semiconductor structure according to claim 1, wherein a material of the p-type semiconductor layer comprises at least one of p-type diamond, p-type NiO, p-type single crystal GaN or p-type polycrystalline GaN.

20. The method for manufacturing the semiconductor structure according to claim 1, further comprising:
etching the n-type semiconductor layer to expose the barrier layer, and form a source region and a drain region, disposing a source electrode in the source region, disposing a drain electrode in the drain region, and disposing a gate electrode on the p-type semiconductor layer located on the trench.
